(19) United States
(12) Patent Application Publication
(10) Pub. No.: US 2026/0150313 A1
(43) Pub. Date: May 28, 2026

(54) SEMICONDUCTOR DEVICE

(71) Applicant: KABUSHIKI KAISHA TOSHIBA, Tokyo (JP)

(72) Inventors: Takahiro OGATA, Kawasaki Kanagawa (JP); Hisao MIYAZAKI, Yokohama Kanagawa (JP); Chiharu OTA, Kawasaki Kanagawa (JP); Masahiko KURAGUCHI, Yokohama Kanagawa (JP); Ryosuke IIJIMA, Setagaya Tokyo (JP); Tatsuo SHIMIZU, Shinagawa Tokyo (JP)

(73) Assignee: KABUSHIKI KAISHA TOSHIBA, Tokyo (JP)

(21) Appl. No.: 19/257,562

(22) Filed: Jul. 2, 2025

(30) Foreign Application Priority Data
Nov. 28, 2024 (JP) 2024-207526

(51) Int. Cl. H10D 8/60; H01L 23/31; H10D 30/66; H10D 62/80

(52) U.S. Cl. CPC H10D 8/60; H10D 30/66; H10D 62/875; H10W 74/137

(57) ABSTRACT

According to one embodiment, a semiconductor device includes a first electrode and a semiconductor member including gallium oxide. The first electrode includes a first face in contact with the semiconductor member. The first face includes an end portion and a non-end portion. A first direction from the semiconductor member to the first electrode crosses a second direction from the end portion to the non-end portion. The semiconductor member includes first to third semiconductor regions. At least a part of the second semiconductor region is between the first semiconductor region and the end portion in the first direction. At least a part of the third semiconductor region overlaps the non-end portion in the first direction. The second semiconductor region includes a first element of at least one selected from the group consisting of F and Cl. The third semiconductor region does not include the first element.

### CROSS-REFERENCE TO RELATED APPLICATIONS

This application is based upon and claims the benefit of priority from Japanese Patent Application No. 2024-207526, filed on Nov. 28, 2024; the entire contents of which are incorporated herein by reference.

### FIELD

Embodiments described herein relate generally to a semiconductor device.

### BACKGROUND

For example, stable operation is desired in semiconductor devices.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a semiconductor device according to the first embodiment;

FIG. 3 is a schematic cross-sectional view illustrating a semiconductor device according to a second embodiment; and

FIG. 4 is a schematic cross-sectional view illustrating a semiconductor device according to the second embodiment.

### DETAILED DESCRIPTION

According to one embodiment, a semiconductor device includes a first electrode and a semiconductor member including gallium oxide. The first electrode includes a first face in contact with the semiconductor member. The first face includes an end portion and a non-end portion. A first direction from the semiconductor member to the first electrode crosses a second direction from the end portion to the non-end portion. The semiconductor member includes a first semiconductor region, a second semiconductor region, and a third semiconductor region. At least a part of the second semiconductor region is between the first semiconductor region and the end portion in the first direction. At least a part of the third semiconductor region overlaps the non-end portion in the first direction. The second semiconductor region includes a first element of at least one selected from the group consisting of F and Cl. The third semiconductor region does not include the first element, or a third concentration of the first element in the third semiconductor region is lower than a second concentration of the first element in the second semiconductor region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

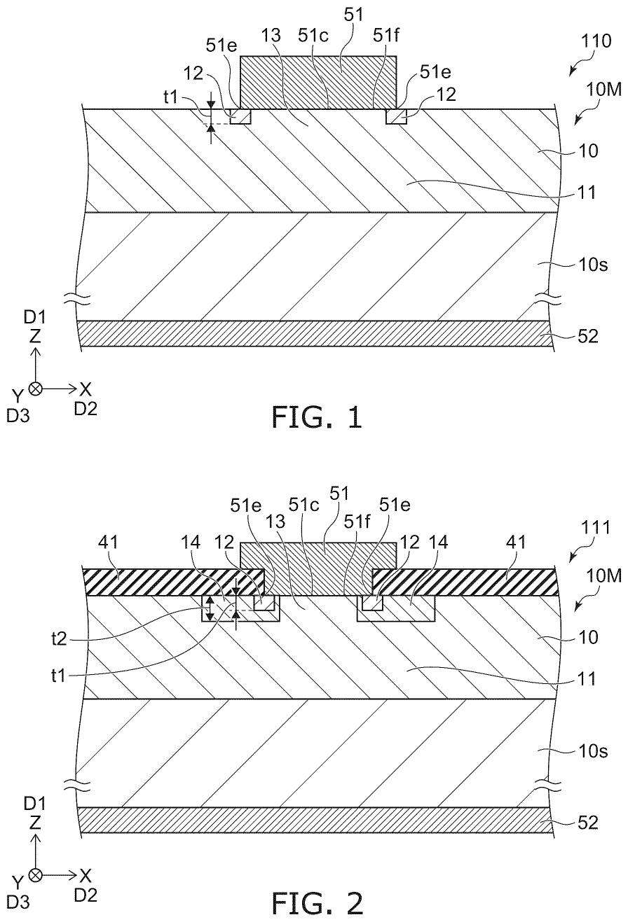

FIG. 1 is a schematic cross-sectional view illustrating a semiconductor device according to a first embodiment.

As shown in FIG. 1, a semiconductor device 110 according to the embodiment includes a first electrode 51 and a semiconductor member 10M.

The semiconductor member 10M includes gallium oxide. The semiconductor member 10M includes, for example, Ga₂O₃. The semiconductor member 10M includes, for example, a crystal.

The first electrode 51 includes a first face 51f that contacts the semiconductor member 10M. The first face 51 f includes an end portion 51e and a non-end portion 51c. The end portion 51e includes an outer edge of the first face 51f. The non-end portion 51c may be provided between multiple portions included in the end portion 51e. The non-end portion 51c is, for example, the inner part of the outer edge.

A first direction D1 from the semiconductor member 10M to the first electrode 51 crosses a second direction D2 from the end portion 51e to the non-end portion 51c.

The first direction D1 is defined as a Z-axis direction. One direction perpendicular to the Z-axis direction is defined as an X-axis direction. A direction perpendicular to the Z-axis direction and the X-axis direction is defined as a Y-axis direction. The second direction D2 may be, for example, the X-axis direction. The first electrode 51 may extend along a third direction D3. The third direction D3 crosses a plane including the first direction D1 and the second direction D2. The third direction D3 may be, for example, the Y-axis direction.

The semiconductor member 10M includes a first semiconductor region 11, a second semiconductor region 12, and a third semiconductor region 13. At least a part of the second semiconductor region 12 is located between the first semiconductor region 11 and the end portion 51e in the first direction D1. At least a part of the third semiconductor region 13 overlaps the non-end portion 51c in the first direction D1. For example, at least a part of the third semiconductor region 13 may be provided between the first semiconductor region 11 and the non-end portion 51c.

The second semiconductor region 12 includes a first element of at least one selected from the group consisting of F and Cl. The third semiconductor region 13 does not include the first element. Or, a concentration of the first element in the third semiconductor region 13 (third concentration) is lower than a concentration of the first element in the second semiconductor region 12 (second concentration).

A high electric field is likely to be applied locally near the end portion 51e of the first electrode 51. For example, the electric field around the end portion 51e of the first electrode 51 is higher than the electric field at the non-end portion 51c of the first electrode 51. The above-mentioned first element is introduced in the region (second semiconductor region 12) where such a high electric field is applied. This can improve the chemical stability of the surface (interface portion) of the gallium oxide. For example, the surface part of the gallium oxide is terminated by the first element. For example, the interface defect density is reduced. For example, the effects of contamination of the surface of the semiconductor member 10M are suppressed. This stabilizes the characteristics. For example, a high breakdown voltage is obtained. According to the embodiment, a semiconductor device that can achieve stable operation can be provided.

The non-end portion 51c of the first electrode 51 becomes a current path in the semiconductor device 110. The concentration of the first element in the third semiconductor region 13 corresponding to at least a part of the current path is low. This results in, for example, a low electrical resistance in the operation. For example, a low on-resistance is obtained.

As shown in FIG. 1, in this example, the semiconductor device 110 further includes a second electrode 52. The semiconductor member 10M is located between the second electrode 52 and the first electrode 51 in the first direction D1. The semiconductor device 110 is, for example, a diode.

For example, the third semiconductor region 13 contacts the non-end portion 51c. A Schottky contact may be formed by the third semiconductor region 13 and the non-end portion 51c. The semiconductor device 110 may be, for example, a Schottky diode.

The first semiconductor region 11 functions, for example, as a drift layer. The semiconductor device 110 may further include a base 10s. The base 10s is located between the second electrode 52 and the first semiconductor region 11. The base 10s may include, for example, gallium oxide (for example, Ga₂O₃). The base 10s may be electrically connected to the second electrode 52.

In the embodiment, the first semiconductor region 11 may not include the first element. Or, a concentration of the first element in the first semiconductor region 11 (first concentration) may be lower than the second concentration.

A thickness of the second semiconductor region 12 along the first direction D1 is defined as a first thickness t1. The first thickness t1 may be, for example, not less than 0.1 nm and not more than 30 nm. The first thickness t1 may be 10 nm or less. When the second semiconductor region 12 being thin is provided, high chemical stability is obtained as well.

In the embodiment, the first semiconductor region 11 may include silicon. By including silicon in the first semiconductor region 11, electrical conductivity can be stably obtained in the first semiconductor region 11. For example, a concentration of silicon in the first semiconductor region 11 (first silicon concentration) may be higher than a concentration of silicon in the second semiconductor region 12 (second silicon concentration). In the second semiconductor region 12 including the first element including at least one selected from the group consisting of F and Cl, the concentration of silicon may be low.

A concentration of silicon in the third semiconductor region 13 (third silicon concentration) may be higher than the concentration of silicon in the second semiconductor region 12 (second silicon concentration). As already explained, the third semiconductor region 13 corresponds to at least a part of the current path. By having a high concentration of silicon in the third semiconductor region 13, a low on-resistance can be easily obtained.

In the embodiment, the second semiconductor region 12 may be formed by locally introducing the first element into the semiconductor layer that will become the first semiconductor region 11. The introduction of the first element may include, for example, ion implantation. The second semiconductor region 12 may be formed, for example, by treatment with a material (for example, liquid or gas) including the first element.

For example, the first semiconductor region 11 may be formed, for example, by epitaxially growing the semiconductor layer that will become the first semiconductor region 11 on the base 10s. In the epitaxial growth, source gases such as GaCl, GaCl₃, and O₂ may be used.

For example, the concentration of the first element in the second semiconductor region 12 may be not less than 1×10¹⁹ cm⁻³ and not more than 1×10²² cm⁻³. The concentration of the first element in the first semiconductor region 11 may be less than 1×10¹⁹ cm⁻³. The concentration of the first element in the third semiconductor region 13 may be less than 1×10¹⁹ cm⁻³.

FIG. 2 is a schematic cross-sectional view illustrating a semiconductor device according to the first embodiment.

As shown in FIG. 2, in a semiconductor device 111 according to the embodiment, a fourth semiconductor region 14 is provided. Except for this, the configuration of the semiconductor device 111 may be the same as the configuration of the semiconductor device 110.

In the semiconductor device 111, the semiconductor member 10M includes a fourth semiconductor region 14. The fourth semiconductor region 14 includes a second element including at least one selected from the group consisting of nitrogen, iron, and magnesium. At least a part of the fourth semiconductor region 14 is located between the first semiconductor region 11 and the end portion 51e. At least a part of the second semiconductor region 12 is located between the fourth semiconductor region 14 and the end portion 51e. The second element may function, for example, as a deep level acceptor.

By providing the fourth semiconductor region 14, for example, the concentration of an electric field is suppressed. This makes it easier to obtain a higher breakdown voltage.

The third semiconductor region 13 may not include the second element (e.g., nitrogen). Or, a concentration of the second element in the third semiconductor region 13 may be lower than a concentration of the second element in the fourth semiconductor region 14.

The first semiconductor region 11 may not include the second element (e.g., nitrogen). Or, a concentration of the second element (e.g., nitrogen) in the first semiconductor region 11 may be lower than a concentration of the second element in the fourth semiconductor region 14.

For example, the concentration of the second element (e.g., nitrogen) in the fourth semiconductor region 14 may be not less than 1.0×10¹⁶ cm⁻³ and not more than 1.0×10¹⁹ cm⁻³. For example, the concentration of the second element (e.g., nitrogen) in the third semiconductor region 13 may be 1.0×10¹³ cm⁻³ and less than 1.0×10¹⁶ cm⁻³. For example, the concentration of the second element (e.g., nitrogen) in the first semiconductor region 11 may be not less than 1.0×10¹³ cm⁻³ and less than 1.0×10¹⁶ cm⁻³.

A concentration of the second element (e.g., nitrogen) in the second semiconductor region 12 may be lower than the concentration of the second element (e.g., nitrogen) in the fourth semiconductor region 14. The concentration of the second element (e.g., nitrogen) in the second semiconductor region 12 may be substantially the same as the concentration of the second element (e.g., nitrogen) in the fourth semiconductor region 14.

As shown in FIG. 2, a thickness of the fourth semiconductor region 14 along the first direction D1 is defined as a second thickness t2. As already explained, the thickness of the second semiconductor region 12 along the first direction D1 is defined as the first thickness t1. The second thickness t2 is thicker than the first thickness t1. More stable characteristics are easier to be obtained.

The first thickness t1 may be, for example, not less than 0.1 nm and not more than 30 nm. The second thickness t2 may be more than 100 nm and not more than 1000 nm.

As shown in FIG. 2, the semiconductor device 111 may further include an insulating member 41. At least a part of the insulating member 41 is provided between the second semiconductor region 12 and the first electrode 51 in the first direction D1, and between the fourth semiconductor region 14 and the first electrode 51 in the first direction D1. The insulating member 41 includes, for example, silicon and at least one selected from the group consisting of nitrogen and oxygen. The insulating member 41 may include, for example, at least one selected from the group consisting of SiO₂, SiN, and SiON. High stability is easily obtained. For example, high reliability is obtained. For example, the semiconductor member 10M is protected by the insulating member 41.

The second semiconductor region 12 may be provided between the insulating member 41 and the first semiconductor region 11, or between the insulating member 41 and the fourth semiconductor region 14. For example, the adverse effect of the movement of silicon from the insulating member 41 to the first semiconductor region 11 is suppressed by the second semiconductor region 12. For example, the adverse effect of the movement of silicon from the insulating member 41 to the fourth semiconductor region 14 is suppressed by the second semiconductor region 12. High stability is obtained.

### Second Embodiment

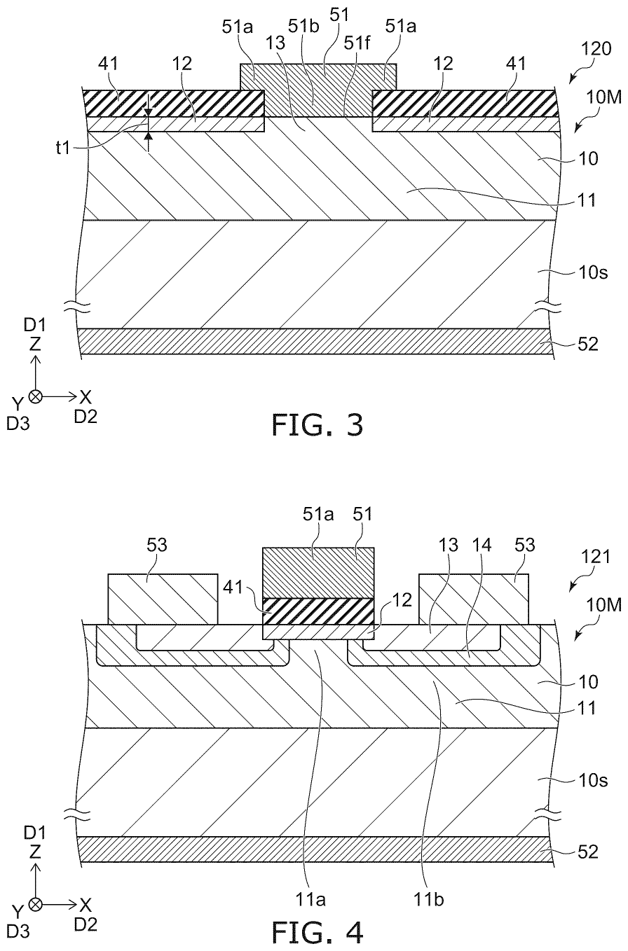

FIG. 3 is a schematic cross-sectional view illustrating a semiconductor device according to a second embodiment.

As shown in FIG. 3, a semiconductor device 120 according to the embodiment includes an insulating member 41 and a semiconductor member 10M.

The insulating member 41 includes silicon. For example, the insulating member 41 includes silicon and at least one selected from the group consisting of nitrogen and oxygen. The insulating member 41 may include at least one selected from the group consisting of SiO₂, SiN, and SiON, for example.

The semiconductor member 10M includes gallium oxide (for example, Ga₂O₃). The semiconductor member 10M includes a first semiconductor region 11 and a second semiconductor region 12. At least a part of the second semiconductor region 12 is located between the first semiconductor region 11 and the insulating member 41.

The second semiconductor region 12 includes a first element of at least one selected from the group consisting of F and Cl. The first semiconductor region 11 does not include the first element. Alternatively, a concentration of the first element in the first semiconductor region 11 (first concentration) is lower than a concentration of the first element in the second semiconductor region 12 (second concentration).

For example, in the second semiconductor region 12, the surface of the gallium oxide is terminated by the first element. This suppresses adverse effects caused by the silicon included in the insulating member 41 formed on the semiconductor member 10M. For example, stable characteristics are easily obtained. According to the embodiment, a semiconductor device that can obtain stable operation can be provided.

In one example, the insulating member 41 may function as a protective film that protects the semiconductor member 10M. As described below, the insulating member 41 may function, for example, as a gate insulating film. By providing the second semiconductor region 12, stable characteristics are easily obtained.

The first thickness t1 of the second semiconductor region 12 may be, for example, not less than 0.1 nm and not more than 30 nm.

As shown in FIG. 3, the semiconductor device 120 may include a first electrode 51. The first electrode 51 includes a first electrode portion 51a. At least a part of the second semiconductor region 12 and at least a part of the insulating member 41 may be provided between the first semiconductor region 11 and the first electrode portion 51a. For example, when a high electric field is applied between the first electrode 51 and the semiconductor member 10M, high stability is obtained as well. For example, a high breakdown voltage is obtained.

As shown in FIG. 3, the first electrode 51 may further include a second electrode portion 51b. The semiconductor member 10M may further include a third semiconductor region 13. The third semiconductor region 13 is in contact with the second electrode portion 51b. The third semiconductor region 13 does not include, for example, the first element. Or, a concentration of the first element in the third semiconductor region 13 (third concentration) is lower than the concentration of the first element in the second semiconductor region 12 (second concentration).

The semiconductor device 120 may include a second electrode 52. The semiconductor member 10M is provided between the second electrode 52 and the first electrode 51. A Schottky contact may be formed by the third semiconductor region 13 and the non-end portion 51c. The semiconductor device 120 may be, for example, a Schottky diode. The third semiconductor region 13 in contact with the second electrode portion 51b becomes at least a part of the current path. The low concentration of the first element in the third semiconductor region 13 makes it easier to obtain, for example, a low on-resistance.

FIG. 4 is a schematic cross-sectional view illustrating a semiconductor device according to the second embodiment.

As shown in FIG. 4, a semiconductor device 121 according to the embodiment includes a third electrode 53. Except for this, the configuration of the semiconductor device 120 may be applied to the semiconductor device 121.

The semiconductor device 121 includes the first electrode 51, the second electrode 52, and the third electrode 53. The semiconductor member 10M is located between the second electrode 52 and the first electrode 51, and between the second electrode 52 and the third electrode 53.

In this example, the first semiconductor region 11 is, for example, of a first conductivity type. The semiconductor member 10M may further include a third semiconductor region 13 and a fourth semiconductor region 14. The third semiconductor region 13 is of the first conductivity type. The fourth semiconductor region 14 may be of a second conductivity type.

The first conductivity type is one of n-type and p-type. The second conductivity type is the other of n-type and p-type. In the following, the first conductivity type is n-type and the second conductivity type is p-type.

The fourth semiconductor region 14 is located between the first semiconductor region 11 and the third electrode 53. The third semiconductor region 13 is located between the fourth semiconductor region 14 and the third electrode 53. The third semiconductor region 13 is electrically connected to the third electrode 53.

For example, current flowing between the second electrode 52 and the third electrode 53 is controlled by a potential of the first electrode 51. The potential of the first electrode 51 may be a potential based on a potential of the third electrode 53. The first electrode 51 functions as, for example, a gate electrode. The second electrode 52 functions as, for example, a drain electrode. The third electrode 53 may function as, for example, a source electrode. The semiconductor device 121 is, for example, a transistor.

The insulating member 41 functions as, for example, a gate insulating film. The second semiconductor region 12 is provided between the insulating member 41 and the first semiconductor region 11. In the second semiconductor region 12, the surface of the gallium oxide is terminated by the first element. For example, stable characteristics are easily obtained.

As shown in FIG. 4, the first semiconductor region 11 may include a first partial region 11a and a second partial region 11b. The second semiconductor region 12 is located between the first partial region 11a and the first electrode 51 in a first direction D1 from the second electrode 52 to the first electrode 51. The fourth semiconductor region 14 is located between the second partial region 11b and the third semiconductor region 13 in the first direction D1. A direction from the first partial region 11a to the third semiconductor region 13 crosses the first direction D1. The direction from the first partial region 11a to the third semiconductor region 13 may be the second direction D2.

In the semiconductor device 121, the third semiconductor region 13 may include silicon. N-type conductivity is stably obtained. The fourth semiconductor region 14 may include a second element (e.g., nitrogen) including at least one element selected from the group consisting of nitrogen, iron, and magnesium. For example, the current is stably controlled. The concentration of silicon in the third semiconductor region 13 may be not less than 1.0×10¹⁶ cm⁻³ and not more than 1.0×10²⁰ cm⁻³. The concentration of the second element (e.g., nitrogen) in the fourth semiconductor region 14 may be, for example, 1.0×10¹⁶ cm⁻³ and not more than 1.0×10¹⁹ cm⁻³.

In the embodiment, information regarding the shapes of the semiconductor member and the electrodes is obtained, for example, by observation with an electron microscope. Information regarding the composition and element concentrations of the semiconductor member, insulating member, and electrodes is obtained, for example, by EDX (Energy Dispersive X-ray Spectroscopy), SIMS (Secondary Ion Mass Spectrometry), or XPS (X-Ray Photoelectron Spectroscopy).

The embodiment may include the following Technical proposals:

### Technical Proposal 1

A semiconductor device, comprising:
a first electrode; and
a semiconductor member including gallium oxide,
the first electrode including a first face in contact with the semiconductor member,
the first face including an end portion and a non-end portion,
a first direction from the semiconductor member to the first electrode crossing a second direction from the end portion to the non-end portion,
the semiconductor member including a first semiconductor region, a second semiconductor region, and a third semiconductor region,
at least a part of the second semiconductor region being between the first semiconductor region and the end portion in the first direction,
at least a part of the third semiconductor region overlapping the non-end portion in the first direction,
the second semiconductor region including a first element of at least one selected from the group consisting of F and Cl,
the third semiconductor region not including the first element, or a third concentration of the first element in the third semiconductor region being lower than a second concentration of the first element in the second semiconductor region.

### Technical Proposal 2

The semiconductor device according to Technical proposal 1, wherein
the first semiconductor region does not include the first element, or a first concentration of the first element in the first semiconductor region is lower than the second concentration.

### Technical Proposal 3

The semiconductor device according to technical proposal 1 or 2, wherein
a third silicon concentration of the silicon in the third semiconductor region is higher than a second silicon concentration of the silicon in the second semiconductor region.

### Technical Proposal 4

The semiconductor device according to Technical proposal 3, wherein
a first silicon concentration of silicon in the first semiconductor region is higher than the second silicon concentration.

### Technical Proposal 5

The semiconductor device according to any one of Technical proposals 1-4, wherein
a first thickness of the second semiconductor region along the first direction is 30 nm or less.

### Technical Proposal 6

The semiconductor device according to any one of Technical proposals 1-4, wherein
the semiconductor member further includes a fourth semiconductor region including a second element including at least one selected from the group consisting of nitrogen, iron, and magnesium,
at least a part of the fourth semiconductor region is between the first semiconductor region and the end portion, and
the at least the part of the second semiconductor region is between the fourth semiconductor region and the end portion.

### Technical Proposal 7

The semiconductor device according to Technical proposal 6, wherein
the third semiconductor region does not include the second element, or a concentration of the second element in the third semiconductor region is lower than a concentration of the second element in the fourth semiconductor region.

### Technical Proposal 8

The semiconductor device according to Technical proposal 7, wherein
the first semiconductor region does not include the second element, or a concentration of the second element in the first semiconductor region is lower than the concentration of the second element in the fourth semiconductor region.

### Technical Proposal 9

The semiconductor device according to any one of Technical proposals 6-8, wherein
a second thickness of the fourth semiconductor region along the first direction is thicker than a first thickness of the second semiconductor region along the first direction.

### Technical Proposal 10

The semiconductor device according to Technical proposal 9, wherein
the first thickness is 30 nm or less, and
the second thickness is more than 100 nm and not more than 1000 nm.

### Technical Proposal 11

The semiconductor device according to any one of Technical proposals 6-10, further comprising:
an insulating member,
at least a part of the insulating member being provided between the second semiconductor region and the first electrode in the first direction, and between the fourth semiconductor region and the first electrode in the first direction.

### Technical proposal 12

The semiconductor device according to any one of Technical proposals 1-11, wherein
the third semiconductor region is in contact with the non-end portion.

### Technical Proposal 13

The semiconductor device according to any one of technical proposals 1-12, further comprising:
a second electrode,
the semiconductor member being between the second electrode and the first electrode in the first direction.

### Technical proposal 14

A semiconductor, device comprising:
an insulating member including silicon and at least one selected from the group consisting of nitrogen and oxygen; and
a semiconductor member including gallium oxide,
the semiconductor member including a first semiconductor region and a second semiconductor region,
at least a part of the second semiconductor region being between the first semiconductor region and the insulating member,
the second semiconductor region including at least one first element selected from the group consisting of F and Cl,
the first semiconductor region not including the first element, or a first concentration of the first element in the first semiconductor region being lower than a second concentration of the first element in the second semiconductor region.

### Technical Proposal 15

The semiconductor device according to Technical proposal 14, wherein
A first thickness of the second semiconductor region is 30 nm or less.

### Technical Proposal 16

The semiconductor device according to Technical proposal 14 or 15, comprising:
a first electrode including a first electrode portion,
the at least the part of the second semiconductor region and at least a part of the insulating member being provided between the first semiconductor region and the first electrode portion.

### Technical Proposal 17

The semiconductor device according to Technical proposal 16, wherein
the first electrode further includes a second electrode portion,
the semiconductor member further includes a third semiconductor region,
the third semiconductor region is in contact with the second electrode portion,
the third semiconductor region does not include the first element, or a third concentration of the first element in the third semiconductor region is lower than the second concentration.

### Technical Proposal 18

The semiconductor device according to Technical proposal 14 or 15, further comprising:
a first electrode;
a second electrode; and
a third electrode,
the semiconductor member being between the second electrode and the first electrode, and between the second electrode and the third electrode,
the first semiconductor region being of a first conductivity type,
the semiconductor member further including a third semiconductor region of the first conductivity type and a fourth semiconductor region,
the fourth semiconductor region being between the first semiconductor region and the third electrode,
the third semiconductor region being between the fourth semiconductor region and the third electrode, and
the third semiconductor region being electrically connected to the third electrode.

### Technical Proposal 19

The semiconductor device according to Technical proposal 18, wherein
the first semiconductor region includes a first partial region and a second partial region,
the second semiconductor region is between the first partial region and the first electrode in a first direction from the second electrode to the first electrode,
the fourth semiconductor region is between the second partial region and the third semiconductor region in the first direction, and
a direction from the first partial region to the third semiconductor region crosses the first direction.

### Technical Proposal 20

The semiconductor device according to Technical proposal 19, wherein
the third semiconductor region includes silicon, and
the fourth semiconductor region includes nitrogen.

According to the embodiment, a semiconductor device that can achieve stable operation can be provided.

In this specification, “electrically connected” includes a state in which multiple conductors are physically in contact with each other and current flows between these multiple conductors. “Electrically connected” includes a state in which a conductor is inserted between multiple conductors and current flows between these multiple conductors.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode; and
a semiconductor member including gallium oxide,
the first electrode including a first face in contact with the semiconductor member,
the first face including an end portion and a non-end portion,
a first direction from the semiconductor member to the first electrode crossing a second direction from the end portion to the non-end portion,
the semiconductor member including a first semiconductor region, a second semiconductor region, and a third semiconductor region,
at least a part of the second semiconductor region being between the first semiconductor region and the end portion in the first direction,
at least a part of the third semiconductor region overlapping the non-end portion in the first direction,
the second semiconductor region including a first element of at least one selected from the group consisting of F and Cl,
the third semiconductor region not including the first element, or a third concentration of the first element in the third semiconductor region being lower than a second concentration of the first element in the second semiconductor region.

2. The semiconductor device according to claim 1, wherein
the first semiconductor region does not include the first element, or a first concentration of the first element in the first semiconductor region is lower than the second concentration.

3. The semiconductor device according to claim 1, wherein
a third silicon concentration of the silicon in the third semiconductor region is higher than a second silicon concentration of the silicon in the second semiconductor region.

4. The semiconductor device according to claim 3, wherein
a first silicon concentration of silicon in the first semiconductor region is higher than the second silicon concentration.

5. The semiconductor device according to claim 1, wherein
a first thickness of the second semiconductor region along the first direction is 30 nm or less.

6. The semiconductor device according to claim 1, wherein
the semiconductor member further includes a fourth semiconductor region including a second element including at least one selected from the group consisting of nitrogen, iron, and magnesium,
at least a part of the fourth semiconductor region is between the first semiconductor region and the end portion, and
the at least the part of the second semiconductor region is between the fourth semiconductor region and the end portion.

7. The semiconductor device according to claim 6, wherein
the third semiconductor region does not include the second element, or a concentration of the second element in the third semiconductor region is lower than a concentration of the second element in the fourth semiconductor region.

8. The semiconductor device according to claim 7, wherein
the first semiconductor region does not include the second element, or a concentration of the second element in the first semiconductor region is lower than the concentration of the second element in the fourth semiconductor region.

9. The semiconductor device according to claim 6, wherein
a second thickness of the fourth semiconductor region along the first direction is thicker than a first thickness of the second semiconductor region along the first direction.

10. The semiconductor device according to claim 9, wherein
the first thickness is 30 nm or less, and
the second thickness is more than 100 nm and not more than 1000 nm.

11. The semiconductor device according to claim 6, further comprising:
an insulating member,
at least a part of the insulating member being provided between the second semiconductor region and the first electrode in the first direction, and between the fourth semiconductor region and the first electrode in the first direction.

12. The semiconductor device according to claim 1, wherein
the third semiconductor region is in contact with the non-end portion.

13. The semiconductor device according to claim 1, further comprising:
a second electrode,
the semiconductor member being between the second electrode and the first electrode in the first direction.

14. A semiconductor device comprising:
an insulating member including silicon and at least one selected from the group consisting of nitrogen and oxygen; and
a semiconductor member including gallium oxide,
the semiconductor member including a first semiconductor region and a second semiconductor region,
at least a part of the second semiconductor region being between the first semiconductor region and the insulating member,
the second semiconductor region including at least one first element selected from the group consisting of F and Cl,
the first semiconductor region not including the first element, or a first concentration of the first element in the first semiconductor region being lower than a second concentration of the first element in the second semiconductor region.

15. The semiconductor device according to claim 14, wherein
a first thickness of the second semiconductor region is 30 nm or less.

16. The semiconductor device according to claim 14, comprising:
a first electrode including a first electrode portion,
the at least the part of the second semiconductor region and at least a part of the insulating member being provided between the first semiconductor region and the first electrode portion.

17. The semiconductor device according to claim 16, wherein
the first electrode further includes a second electrode portion,
the semiconductor member further includes a third semiconductor region,
the third semiconductor region is in contact with the second electrode portion,
the third semiconductor region does not include the first element, or a third concentration of the first element in the third semiconductor region is lower than the second concentration.

18. The semiconductor device according to claim 14, further comprising:
a first electrode;
a second electrode; and
a third electrode,
the semiconductor member being between the second electrode and the first electrode, and between the second electrode and the third electrode,
the first semiconductor region being of a first conductivity type,
the semiconductor member further including a third semiconductor region of the first conductivity type and a fourth semiconductor region,
the fourth semiconductor region being between the first semiconductor region and the third electrode,
the third semiconductor region being between the fourth semiconductor region and the third electrode, and
the third semiconductor region being electrically connected to the third electrode.

19. The semiconductor device according to claim 18, wherein
the first semiconductor region includes a first partial region and a second partial region,
the second semiconductor region is between the first partial region and the first electrode in a first direction from the second electrode to the first electrode,
the fourth semiconductor region is between the second partial region and the third semiconductor region in the first direction, and
a direction from the first partial region to the third semiconductor region crosses the first direction.

20. The semiconductor device according to claim 19, wherein
the third semiconductor region includes silicon, and
the fourth semiconductor region includes nitrogen.
